(19) United States
(12) Patent Application Publication
(10) Pub. No.: US 2025/0079166 A1
(43) Pub. Date: Mar. 6, 2025

(54) METHODS FOR PROTECTING TO REUSE SILICON CARRIER WAFER BASED ON IR LASER LIFT-OFF PROCESS

(71) Applicant: Tokyo Electron Limited, Tokyo (JP)

(72) Inventors: Panupong JAIPAN, Albany, NY (US); Matthew BARON, Albany, NY (US); Kandabara TAPILY, Albany, NY (US); Ilseok SON, Albany, NY (US); Arkalgud SITARAM, Albany, NY (US); Yohei YAMASHITA, Kumamoto (JP); Yasutaka MIZOMOTO, Kumamoto (JP); Yoshihiro TSUTSUMI, Tokyo (JP); Yoshihiro KONDO, Kumamoto (JP)

(21) Appl. No.: 18/786,164

(22) Filed: Jul. 26, 2024

Related U.S. Application Data
(60) Provisional application No. 63/535,095, filed on Aug. 29, 2023.

(51) Int. Cl. H01L 21/02; H01L 21/306

(52) U.S. Cl. CPC H01L 21/02532; H01L 21/30625

(57) ABSTRACT

Semiconductor devices and corresponding methods of manufacture are disclosed. The method includes forming a first device structure on a first substrate, a first laser liftoff layer on the first device structure, a protective layer on the first laser liftoff layer, and a second substrate on the protective layer. The method includes de-attaching, through applying radiation on the first laser liftoff layer, the protective layer from the first laser liftoff layer, with a first surface of the second substrate remaining in contact with a second surface of the protective layer. The protective layer is transparent to the radiation.

### CROSS-REFERENCE TO RELATED APPLICATION

This application claims priority to and the benefit of U.S. Provisional Application No. 63/535,095, filed Aug. 29, 2023, which is incorporated herein by reference in its entirety for all purposes.

### FIELD OF THE DISCLOSURE

This disclosure relates generally to methods for fabricating semiconductor devices and in particular to methods for fabricating such devices using an IR laser liftoff process.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. In accordance with such a scaling trend, multiple semiconductor dies, each of which may have different functions, can be bonded to each other. A carrier substrate is generally used in the bonding process, so as to provide mechanical support for one of the semiconductor dies. In the existing technologies (e.g., mechanical grinding, laser liftoff process), the carrier substrate typically cannot be reused.

### SUMMARY

One aspect of the present disclosure is directed to a method for fabricating semiconductor devices. The method may include providing a bonded structure comprising a first substrate and a second substrate, a device structure between the first substrate and the second substrate, a release layer between the device structure and the first substrate, and a protective layer between the release layer and the first substrate. The device structure includes a memory device formed on the second substrate. The method may include applying radiation to the release layer to detach the first substrate and protective layer from the release layer. The protective layer is transparent to the radiation.

In some embodiments, the protective layer includes silicon germanium, and the radiation includes infrared laser light with a wavelength of about 2 micrometers (μm) to about 10 μm.

In some embodiments, the step of providing a bonded structure comprises bonding the device structure to the second substrate through an oxide layer.

In some embodiments, after detaching the first substrate and protective layer from the release layer, the method may further include: polishing a surface of the protective layer through a chemical-mechanical polishing (CMP) process; and epitaxially growing an additional layer from the polished surface.

In some embodiments, the release layer is a first release layer, and the device structure is a first device structure, the method further comprising: providing a second release layer on the additional layer; and providing a second device structure on the second release layer.

In some embodiments, the method may further include removing the protective layer to expose a surface of the first substrate; and planarizing the surface of the first substrate through a gas cluster beam (GCB) process.

In some embodiments, the release layer is a first release layer, and the device structure is a first device structure, and the method may further include: providing a second release layer on the first substrate; and providing a second device structure on the second release layer.

In some embodiments, after detaching the first substrate and protective layer from the release layer, the method further comprises polishing a surface of the protective layer through a gas cluster beam (GCB) process to form a polished protective layer.

In some embodiments, the release layer is a first release layer, and the device structure is a first device structure, and the method may further include: providing a second release layer on the polished protective layer; and providing a second device structure on the second release layer.

In another aspect of the present disclosure is directed to a method for fabricating semiconductor devices, the method may include providing a bonded structure comprising a first substrate bonded to a second substrate, a device structure including a memory device provided between the first substrate and the second substrate, and a release layer between the device structure and the first substrate. The method may include applying radiation to the release layer to detach the first substrate from the release layer. The method may include planarizing first substrate. The method may include reusing the first substrate for a subsequent bonding process, wherein the subsequent bonding process includes bonding another device structure to the first substrate through another release layer.

In some embodiments, the first substrate comprises a base substrate and a protective layer between the base substrate and the release layer, and the method may further include planarizing at least a portion of the protective layer.

In some embodiments, the first substrate comprises a base substrate and a protective layer between the base substrate and the release layer, and the method may further include removing the protective layer before planarizing the base substrate.

In some embodiments, the protective layer includes silicon germanium, and the radiation includes infrared laser light with a wavelength of about 2 micrometers (μm) to about 10 μm.

In some embodiments, the method may further include polishing a surface of the protective layer through a chemical-mechanical polishing (CMP) process to form a polished protective layer; and epitaxially growing an additional layer from the polished protective layer.

In some embodiments, the transfer layer is a first transfer layer, and the method may further include forming a second transfer layer over the polished protective layer.

In some embodiments, the planarizing is performed using a gas cluster beam (GCB) process.

Another aspect of the present disclosure is directed to a method for fabricating semiconductor devices, the method may include providing a substrate having structural damage caused by exposure to a radiation source in a first bonding process, the structural damage including an intermittent, semi-regular, or regular array of peaks. The method may include planarizing the substrate by flattening or removing the peaks. The method may include providing and processing a series of layers on the substrate to form a device structure including a memory device.

In some embodiments, the substrate includes silicon or silicon germanium and utilizing the substrate comprises epitaxially growing an additional layer of silicon or silicon germanium over the substrate.

In some embodiments, the substrate includes a base substrate and a protective layer.

In some embodiments, the protective layer is removed and planarizing the substrate comprises planarizing the base substrate.

In some embodiments, planarizing the substrate comprises planarizing the base protective layer.

These and other aspects and implementations are discussed in detail below. The foregoing information and the following detailed description include illustrative examples of various aspects and implementations and provide an overview or framework for understanding the nature and character of the claimed aspects and implementations. The drawings provide illustrations and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing.

FIG. 1 illustrates a flowchart of a method to process one or more semiconductor devices, according to an embodiment.

FIGS. 2A-2E show cross-sectional views of a semiconductor device, according to an embodiment.

FIG. 3 illustrates a flowchart of another method to process one or more semiconductor devices, according to an embodiment.

FIGS. 4A-4F show cross-sectional views of a semiconductor device, according to an embodiment.

FIGS. 5A-5G show cross-sectional views of a semiconductor device, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

The present disclosure provides various embodiments of methods for forming a semiconductor device using a laser liftoff layer to remove a carrier substrate. Such a carrier substrate is generally formed as a sacrificial substrate attached to one side of a device structure, so as to provide mechanical support for the device structure while forming various transistors and interconnect structures (which are typically referred to as front-end-of-line (FEOL) processing and back-end-of-line (BEOL) processing, respectively). In existing technologies, such a carrier substrate is removed through a polishing process (e.g., a chemical-mechanical polishing (CMP) process), which may sometimes damage the already formed transistors and interconnect structures. With the laser liftoff layer, the carrier substrate is successfully removed through applying IR Laser Lift-Off (LLO) process on the laser liftoff release layer. However, after such a radiation process, a surface of the carrier substrate (contacting the laser liftoff release layer) is typically damaged, which significantly shortens the lifetime of the carrier substrate. For example, the carrier substrate cannot be reused. In this regard, the disclosed method can advantageously avoid these issues. For example, the method, as disclosed herein, includes forming a protective layer, between a laser liftoff release layer and a carrier substrate. Further, the protective layer is transparent to the IR Laser process radiation applied to the IR laser liftoff release layer. As such, without much mechanical force applied to the transistors or the interconnect structures, the carrier substrate can be easily removed through applying the radiation on the laser liftoff layer, while causing no damage on the carrier substrate as it is protected by the protective layer.

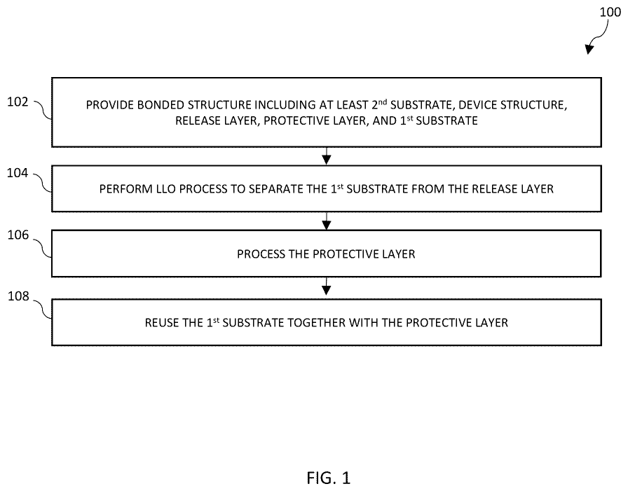

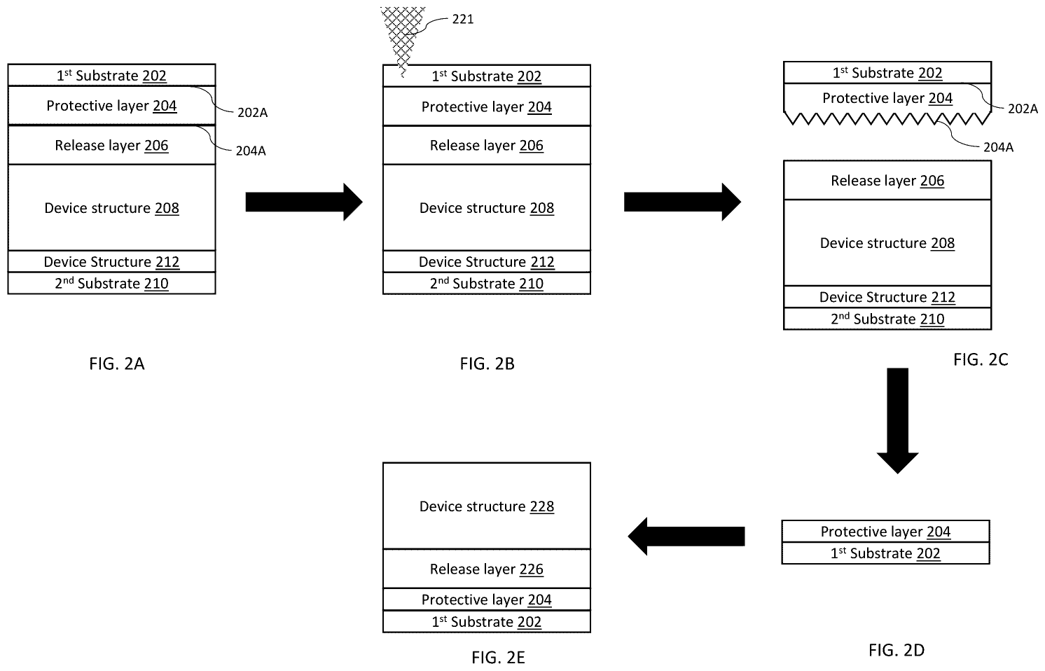

FIG. 1 illustrates a flowchart of a method 100 to process one or more bonded structures, according to one or more embodiments of the present disclosure. At least some of the operations (or steps) of the method 100 can be used to form a device structure (e.g., a NAND memory device) over a carrier substrate, and such a carrier substrate can be later removed (e.g., lifted off) without being damaged. As a non-limiting example, the operations of the method 100 may be associated with cross-sectional views of one or more example bonded structures at various fabrication stages as shown in FIGS. 2A-2E, respectively, which will be discussed in further detail below. It should be noted that the method 100 is merely an example and is not intended to limit the present disclosure. Accordingly, it is understood that additional operations may be provided before, during, and after the method 100 of FIG. 1, and that some other operations may only be briefly described herein.

Corresponding to operation 102 of FIG. 1, FIG. 2A is a cross-sectional view of a first bonded structure (being shown upside down), in which a carrier substrate 202 is overlaid by a protective layer 204, which is overlaid by a laser liftoff layer (or release layer) 206, which is overlaid by a device structure 208, which is overlaid by a second substrate 210, at one of the various stages of fabrication, in accordance with various embodiments of the present disclosure. The carrier substrate 202 is configured to serve as a carrier substrate that can be reused through the currently disclosed methods, and thus, the carrier substrate 202 may be sometimes referred to as a carrier substrate 202.

In some embodiments, the device structure 208 may include various functional devices (e.g., NAND memory devices) formed on the carrier substrate 202. Device structure 208 may alternatively comprise any transfer layer, such as one or more conductive, dielectric, semiconductor, and/or optical layers that are to be formed on a first substrate to be bonded to a second substrate. The carrier substrate 202 can serve as a carrier substrate, which can be reused in accordance with various embodiments of the present disclosure. The device structure 208 can be attached to the carrier substrate 202 through the protective layer 204 and the release layer 206. That is, the protective layer 204 can overlay or otherwise protect a surface 202A of the carrier substrate 202, which allows the surface 202A not to be in direct contact with the release layer 206. Instead, the protective layer 204 can have its surface 204A in direct contact with the release layer 206.

After forming the device structure 208 on the carrier substrate 202, such a structure can be attached (e.g., bonded) to the second substrate 210 through another device structure 212, as shown in FIG. 2A. In the example where the device structure 208 include a memory device, the device structure 212 may include a number of logic devices that are configured to control or otherwise operate the memory device. Additionally or alternatively, device structure 212 may include interconnect metallization layers, oxide layers for forming a bond between the device structure 208 and 2^{nd} substrate 210, etc. In general, the bonded structure shown in FIG. 2A can be formed by at least some of the following processes: (a) providing the carrier substrate 202; (b) providing the second substrate 210; (c) forming the protective layer 204 on the carrier substrate 202; (d) forming the release layer 206 on the protective layer 204; (e) forming the device structure 208 on the release layer 206; (f) forming the device structure 212 on the second substrate 210; and (g) bonding the device structure 208 (with itself and other stacked structures, e.g., 202 to 206, being flipped) to the device structure 212. It should be appreciated that some of the processes can be performed concurrently such as, for example, processes (a) and (b), processes (c) to (c) and process (f).

The carrier substrate 202 and the second substrate 210 may each be a semiconductor substrate, such as a bulk semiconductor, a semiconductor-on-insulator (SOI) substrate, or the like, which may be doped (e.g., with a p-type or an n-type dopant) or undoped. In some embodiments, the substrate 202/210 may be a wafer, such as a silicon wafer, or a die, such a silicon die. In other embodiments, substrate 202 may be one of a die or wafer and 210 may be the other of a die or wafer thereby bearing a die to wafer configuration and bonding technique. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. For example, the semiconductor material of the substrate 202/210 may include silicon; a compound semiconductor including silicon carbide, gallium arsenic, gallium phosphide, indium phosphide, indium arsenide, and/or indium antimonide; an alloy semiconductor including, GaAsP, AlInAs, AlGaAs, GaInAs, GaInP, and/or GaInAsP; or combinations thereof.

In some embodiments, prior to forming the device structure 208, the protective layer 204 and the release layer 206 may be sequentially formed on the carrier substrate 202 (e.g., a carrier wafer). The protective layer 204 may include a semiconductor material (e.g., silicon germanium) epitaxially grown from the carrier substrate 202. With such a material, the protective layer 204 may be transparent to radiation (e.g., infrared laser) that is applied to the release layer 206. The release layer 206 can be induced with thermal stress, upon being applied with radiation, thereby allowing the carrier substrate 202 to be later removed from the device structure 208. The release layer 206 may include a material selected from the group consisting of: silicon nitride, silicon oxynitride, silicon oxycarbonitride, silicon carbonitride, titanium nitride, metal, and metal oxide. The release layer 206 may be deposited or thermally grown over the protective layer 204. The release layer 206 may comprise a plurality of layers, such as reflective and absorption layers to achieve the release of the substrate 402 from the device structure 408 without damaging the device structure 208. Such details are provided elsewhere, e.g., US patent application Ser. No. [need to add before filing], which is incorporated herein by reference in its entirety.

Corresponding to operation 104 of FIG. 1, FIG. 2B and FIG. 2C are cross-sectional views of the first bonded structure (being shown upside down), in which a laser liftoff (LLO) process 221 is performed to separate the carrier substrate 202 from the release layer 206, at one of the various stages of fabrication, in accordance with various embodiments of the present disclosure.

In various embodiments, the LLO process 221 may include irradiating radiation or otherwise optical energy (e.g., a laser beam) on the release layer 206 through the carrier substrate 202 and the protective layer 204. In one aspect, the radiation may include infrared laser light with a wavelength of about 2 micrometers (μm) to about 10 μm. In another aspect, the radiation may include infrared laser light with a wavelength of about 3 μm to about 10 μm. The carrier substrate 202 and the protective layer 204 may be optically transparent to a wavelength of the optical energy. As a non-limiting example, the laser radiation incident upon the carrier substrate 202 may be radiation from a Nd:YAG, fiber, diode, Nd:YVO₄, or otherwise semiconductor lasers. The energy, passing through the carrier substrate 202 and the protective layer 204, is then absorbed by the release layer 206 which causes thermal stress in the release layer 206. The workpiece (which may include the release layer 206 (if still remains), the device structure 208, and the second substrate 210) can be released, disconnected, or otherwise decoupled from the carrier substrate 202 as a carrier substrate that has its surface 202A kept protected by the protective layer 204. The LLO process 221 can be performed in an ambient environment, in some embodiments.

In certain cases, after performing a LLO process, a surface that was in contact with a corresponding release layer 206 may be damaged. For example, in FIG. 2C, the surface 204A of the protective layer 204 may have a number of protrusions after the LLO process 221. Such protrusions may appear as an array of sharp peaks that are caused by the intermittent shining ad scanning of the laser light. In various embodiments of the present disclosure, the protective layer 204 can serve as a protection for the carrier substrate 202 as a carrier wafer, which can be reused for forming other device structures. In one aspect of the present disclosure, such a damaged surface 204A may be repaired such that the carrier substrate 202 together with the protective layer 204 can both be reused.

Corresponding to operation 106 of FIG. 1, FIG. 2D is a cross-sectional view of the protective layer 204 being processed to repair the damaged surface 204A, at one of the various stages of fabrication, in accordance with various embodiments of the present disclosure.

In one aspect of the present disclosure, a chemical-mechanical polishing (CMP) process may be performed to polish the damaged surface 204A. Optionally, following the CMP process, an epitaxial growth may be performed to form another layer on the protective layer 204. Accordingly, a thickness of the protective layer 204 may be restored such that the carrier substrate 202 and the protective layer 204 may both be reused.

Additionally or alternatively, a gas cluster beam (GCB) process may be performed to polish the damaged surface 204A. A GCB process typically involves a focused beam enabled by clusters of gas molecules to remove surface material in molecular scale. The gas clusters bombard into the molecules of a surface (e.g., surface 204A) and remove the surface by physical and chemical means. The amount of material removed is controlled by the total energy applied on the gas cluster and the composition of gas cluster molecules. Advantageously, the GCB may be directed to specific regions where the damaged surface may demonstrate one or more peaks caused by the debonding laser, which may leave a surface with intermittent, semi-regular arrays or ordered arrays of peaks. Thus, the GCB can specifically target non-uniformities as opposed to the entire surface of damaged surface 204A to flatten or remove the peaks without substantially planarizing other regions of the surface.

Corresponding to operation 108 of FIG. 1, FIG. 2E is a cross-sectional view of a second bonded structure, in which the carrier substrate 202 and the protective layer 204 are reused as a carrier substrate for another device structure 228, at one of the various stages of fabrication, in accordance with various embodiments of the present disclosure.

After processing the surface 204A (with the protective layer 204 remaining in contact with the carrier substrate 202), yet another device structure 228 can be formed on the carrier substrate 202 with another release layer 226 interposed between the device structure 228 and the protective layer 204. As such, such a structure can be bonded to another substrate (e.g., operation 102), followed by another IR laser lift-off process (operation 104) and further followed by another repair process performed on the same protective layer 204 (operation 106).

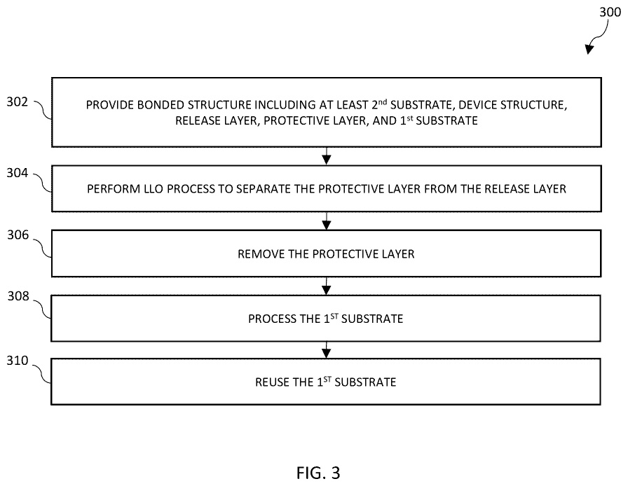

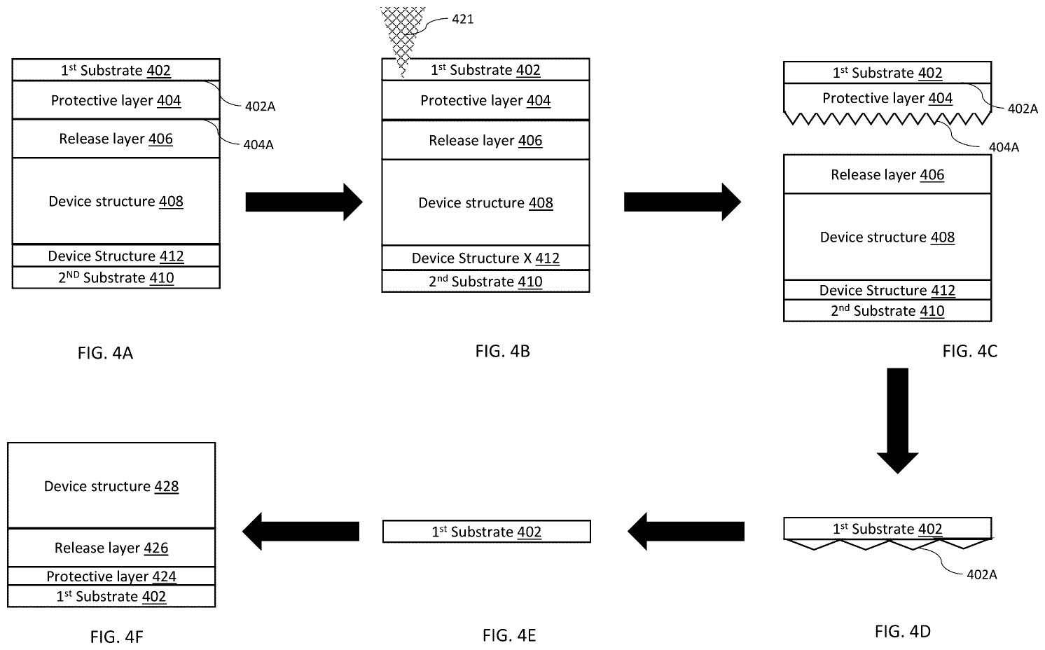

FIG. 3 illustrates a flowchart of another method 300 to process one or more bonded structures, according to one or more embodiments of the present disclosure. At least some of the operations (or steps) of the method 300 can be used to form a device structure (e.g., a NAND memory device) over a carrier substrate, and such a carrier substrate can be later removed (e.g., lifted off) without being damaged. As a non-limiting example, the operations of the method 300 may be associated with cross-sectional views of one or more example bonded structures at various fabrication stages as shown in FIGS. 4A-4F, respectively, which will be discussed in further detail below. It should be noted that the method 300 is merely an example and is not intended to limit the present disclosure. Accordingly, it is understood that additional operations may be provided before, during, and after the method 300 of FIG. 3, and that some other operations may only be briefly described herein.

Corresponding to operation 302 of FIG. 3, FIG. 4A is a cross-sectional view of a first bonded structure (being shown upside down), in which a first substrate 402 is overlaid by a protective layer 404, which is overlaid by a laser liftoff layer (or release layer) 406, which is overlaid by a device structure 408, which is overlaid by a second substrate 410, at one of the various stages of fabrication, in accordance with various embodiments of the present disclosure. The first substrates 402 is configured to serve as a carrier substrate that can be reused through the currently disclosed methods, and thus, the first substrate may sometimes be referred to as carrier substrate 402.

In some embodiments, the device structure 408 may include various functional devices (e.g., NAND memory devices) formed on the carrier substrate 402. Device structure 408 may alternatively comprise any transfer layer, such as one or more conductive, dielectric, semiconductor, and/or optical layers that are to be formed on a first substrate to be bonded to a second substrate. The carrier substrate 402 can serve as a carrier substrate, which can be reused in accordance with various embodiments of the present disclosure. The device structure 408 can be attached to the first substrate carrier 402 through the protective layer 404 and the release layer 406. That is, the protective layer 404 can overlay or otherwise protect a surface 402A of the carrier substrate 402, which allows the surface 402A not to be in direct contact with the release layer 406. Instead, the protective layer 404 can have its surface 404A in direct contact with the release layer 406.

After forming the device structure 408 on the carrier substrate 402, such a structure can be attached (e.g., bonded) to the second substrate 410 through another device structure 412, as shown in FIG. 4A. In the example where the device structure 408 include a memory device, the device structure 412 may include a number of logic devices that are configured to control or otherwise operate the memory device. In general, the bonded structure shown in FIG. 4A can be formed by at least some of the following processes: (a) providing the carrier substrate 402; (b) providing the second substrate 410; (c) forming the protective layer 404 on the carrier substrate 402; (d) forming the release layer 406 on the protective layer 404; (e) forming the device structure 408 on the release layer 406; (f) forming the device structure 412 on the second substrate 410; and (g) bonding the device structure 408 (with itself and other stacked structures, e.g., 402 to 406, being flipped) to the device structure 412. It should be appreciated that some of the processes can be performed concurrently such as, for example, processes (a) and (b), processes (c) to (c) and process (f).

The carrier substrate 402 and the second substrate 410 may each be a semiconductor substrate, such as a bulk semiconductor, a semiconductor-on-insulator (SOI) substrate, or the like, which may be doped (e.g., with a p-type or an n-type dopant) or undoped. In some embodiments, the substrate 402/410 may be a wafer, such as a silicon wafer, or a die, such a silicon die. In other embodiments, substrate 202 may be one of a die or wafer and 410 may be the other of a die or wafer thereby bearing a die to wafer configuration and bonding technique. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. For example, the semiconductor material of the substrate 402/410 may include silicon; a compound semiconductor including silicon carbide, gallium arsenic, gallium phosphide, indium phosphide, indium arsenide, and/or indium antimonide; an alloy semiconductor including, GaAsP, AlInAs, AlGaAs, GaInAs, GaInP, and/or GaInAsP; or combinations thereof.

In some embodiments, prior to forming the device structure 408, the protective layer 404 and the release layer 406 may be sequentially formed on the carrier substrate 402. The protective layer 404 may include a semiconductor material (e.g., silicon germanium) epitaxially grown from the carrier substrate 402. With such a material, the protective layer 404 may be transparent to radiation (e.g., infrared laser) that is applied to the release layer 406. The release layer 406 can be induced with thermal stress upon being applied with radiation, thereby allowing the carrier substrate 402 to be later removed from the device structure 408. The release layer 406 may include a material selected from the group consisting of: silicon nitride, silicon oxynitride, silicon oxycarbonitride, silicon carbonitride, titanium nitride, metal, and metal oxide. The release layer 406 may be deposited or thermally grown over the protective layer 404. As with release layer 206, the release layer 406 may comprise a plurality of layers, such as reflective and absorption layers to achieve the release of the substrate 402 from the device structure 408 without damaging the device structure 408. Such details are provided elsewhere, e.g., US patent application Ser. No. [need to add before filing], which is incorporated herein by reference in its entirety.

Corresponding to operation 304 of FIG. 3, FIG. 4B and FIG. 4C are cross-sectional views of the first bonded structure (being shown upside down), in which a laser liftoff (LLO) process 421 is performed to separate the carrier substrate 402 from the release layer 406, at one of the various stages of fabrication, in accordance with various embodiments of the present disclosure.

In various embodiments, the LLO process 421 may include irradiating radiation or otherwise optical energy (e.g., a laser beam) on the release layer 406 through the carrier substrate 402 and the protective layer 404. The radiation may include infrared laser light with a wavelength of about 2 micrometers (μm) to about 10 μm. The carrier substrate 402 and the protective layer 404 may be optically transparent to a wavelength of the optical energy. As a non-limiting example, the laser radiation incident upon the carrier substrate 402 may be 1.064 μm radiation from a Nd:YAG, fiber, diode, Nd:YVO₄, or otherwise semiconductor lasers. The energy, passing through the carrier substrate 402 and the protective layer 404, is then absorbed by the release layer 406 which causes thermal stress in the release layer 406. The workpiece (which may include the release layer 406 (if still remains), the device structure 408, and the second substrate 410) can be released, disconnected, or otherwise decoupled from the carrier substrate 402 that has its surface 402A kept protected by the protective layer 404. The LLO process 421 can be performed in an ambient environment, in some embodiments.

In certain cases, after performing a LLO process, a surface that was in contact with a corresponding release layer may be damaged. For example, in FIG. 4C, the surface 404A of the protective layer 404 may have a number of protrusions 404A after the LLO process 421. In various embodiments of the present disclosure, the protective layer 404 can serve as a protection for the carrier substrate 402, which can be reused for forming other device structures. In one aspect of the present disclosure, the damaged protective layer 404 can be disposed, i.e., keeping only the carrier substrate 402 for reuse.

Corresponding to operation 306 of FIG. 3, FIG. 4D is a cross-sectional view of the protective layer 404 (FIG. 4C) being removed, at one of the various stages of fabrication, in accordance with various embodiments of the present disclosure.

In some embodiments, one or more (e.g., wet) etching processes may be performed to remove the protective layer 404. For example, an etching solution (e.g., mixtures of hydrofluoric acid (HF), hydrogen peroxide (H₂O₂) and acetic acid (CH₃COOH, HAc)) having an etching selectivity between the materials of the carrier substrate 402 and the protective layer 404 may be used to remove the (damaged) protective layer 404. In certain cases, after removing the protective layer 404, the surface 402A that was overlaid by the protective layer 404 may be damaged, as shown in FIG. 4D.

Corresponding to operation 308 of FIG. 3, FIG. 4E is a cross-sectional view of the carrier substrate 402 being processed to repair the damaged surface 402A, at one of the various stages of fabrication, in accordance with various embodiments of the present disclosure. It should be appreciated that the operation 308 can be optional if the surface 402A has not been damaged during the removal of the protective layer 404.

In one aspect of the present disclosure, a chemical-mechanical polishing (CMP) process may be performed to polish the damaged surface 402A. Optionally, following the CMP process, an epitaxial growth may be performed to form another layer on the carrier substrate 402. Accordingly, a thickness of the carrier substrate 402 may be restored for extensive reuse. In another aspect of the present disclosure, a gas cluster beam (GCB) process may be performed to polish the damaged surface 402A. A GCB process typically involves a focused beam enabled by clusters of gas molecules to remove surface material in molecular scale. The gas clusters bombard into the molecules of a surface (e.g., surface 402A) and remove the surface by physical and chemical means. The amount of material removed is controlled by the total energy applied on the gas cluster and the composition of gas cluster molecules.

Corresponding to operation 310 of FIG. 3, FIG. 4F is a cross-sectional view of a second bonded structure, in which the carrier substrate 402 is reused as a carrier substrate for another device structure 428, at one of the various stages of fabrication, in accordance with various embodiments of the present disclosure.

After processing the surface 402A (if needed), another device structure 428 can be formed on the first carrier substrate 402 with another protective layer 424 and another release layer 426 interposed between the device structure 428 and the carrier substrate 402. As such, such a structure can be bonded to another substrate (e.g., operation 302), followed by another liftoff process (operation 304) and further followed by another repair process performed on the same carrier substrate 402 (operation 308).

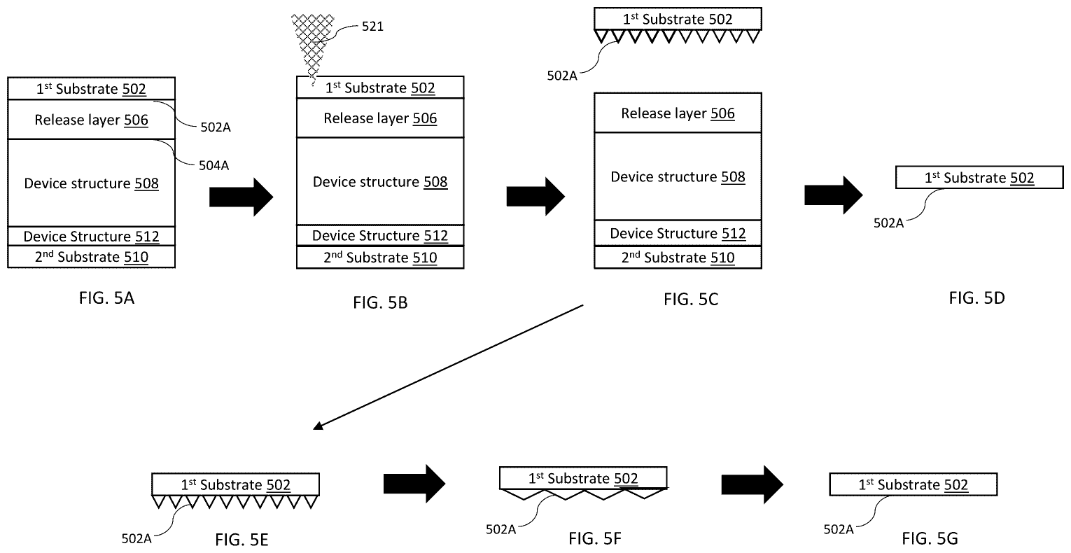

FIGS. 5A, 5B, 5C, and 5D illustrate a diagram flow for reusing a carrier substrate associated with cross-sectional views of one or more example bonded structures, at various fabrication stages, respectively; and FIGS. 5A, 5B, 5C, 5D, 5E, 5F, and 5G illustrate another diagram flow for reusing a carrier substrate associated with cross-sectional views of one or more example bonded structures, at various fabrication stages, respectively.

Referring first to FIG. 5A, a bonded structure (being shown upside down) includes a first substrate 502 overlaid by a laser liftoff layer (or release layer) 506, which is overlaid by a device structure 508, which is overlaid by a second substrate 510. In some embodiments, the device structure 508 may include various functional devices (e.g., NAND memory devices) formed on the first substrate 502. The first substrate 502 can serve as a carrier substrate, which can be reused in accordance with various embodiments of the present disclosure. The device structure 508 can be attached to the first substrate 502 through the release layer 506. After forming the device structure 508 on the first substrate 502, such a structure can be attached (e.g., bonded) to another device structure 512 formed on the second substrate 510, as shown in FIG. 5A.

The first substrate 502 and the second substrate 510 may each be a semiconductor substrate, such as a bulk semiconductor, a semiconductor-on-insulator (SOI) substrate, or the like, which may be doped (e.g., with a p-type or an n-type dopant) or undoped. In some embodiments, the substrate 502, 510 may be a wafer or die, such as a silicon wafer or die. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. For example, the semiconductor material of the substrate 502, 510 may include silicon; a compound semiconductor including silicon carbide, gallium arsenic, gallium phosphide, indium phosphide, indium arsenide, and/or indium antimonide; an alloy semiconductor including, GaAsP, AlInAs, AlGaAs, GaInAs, GaInP, and/or GaInAsP; or combinations thereof.

In some embodiments, prior to forming the device structure 508, the release layer 506 may be formed on the first substrate 502. The release layer 506 can be induced with thermal stress, upon being applied with radiation, thereby allowing the first substrate 502 to be later removed from the device structure 508. The release layer 506 may include a material selected from the group consisting of: silicon nitride, silicon oxynitride, silicon oxycarbonitride, silicon carbonitride, titanium nitride, metal, and metal oxide. The release layer 506 may be deposited or thermally grown over the first substrate 502.

Referring next to FIG. 5B, a laser liftoff (LLO) process 521 may include irradiating radiation or otherwise optical energy (e.g., a laser beam) on the release layer 506 through the first substrate 502. The radiation may include infrared laser light with a wavelength of about 2 micrometers (μm) to about 10 μm. The first substrate 502 may be optically transparent to a wavelength of the optical energy (e.g., IR laser with a wavelength from 2 μm to 10 μm). As a non-limiting example, the laser radiation incident upon the first substrate 502 may be 1.064 μm radiation from a Nd:YAG, fiber, diode, Nd:YVO₄, or otherwise semiconductor lasers. The energy, passing through the first substrate 502, is then absorbed by the release layer 506 which causes thermal stress in the release layer 506. The workpiece (while may include the release layer 506 (if still remains), the device structure 508, and the second substrate 510) can be released, disconnected, or otherwise decoupled from the first substrate 502. The LLO process 521 can be performed in an ambient environment, in some embodiments.

In certain cases, after performing a LLO process, a surface that was in contact with a corresponding release layer may be damaged. For example, in FIG. 5C, the surface 502A of the first carrier substrate 502 may have a number of protrusions after the LLO process 521. In some embodiments of the present disclosure, such a damaged surface 502A may be repaired such that the first substrate 502 can be reused.

For example, in FIG. 5D, a gas cluster beam (GCB) process may be performed to polish the damaged surface 502A, so as to allow the first substrate 502 to be reused. A GCB process typically involves a focused beam enabled by clusters of gas molecules to remove surface material in molecular scale. The gas clusters bombard into the molecules of a surface (e.g., surface 502A) and remove the surface by physical and chemical means. The amount of material removed is controlled by the total energy applied on the gas cluster and the composition of gas cluster molecules.

For another example, in FIG. 5E, a GCB process (e.g., with lower energy) may first be applied on the damaged surface 502A. As such, the protrusion present on the surface 502A may be mitigated. Next, in FIG. 5F, a chemical-mechanical polishing (CMP) process may be performed to further polish the surface 502A so as to allow the first substrate 502 to be reused, as shown in FIG. 5G.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variatCoions are intended to be covered by the scope of this disclosure. As such, the foregoing descriptions of embodiments of the invention are not intended to be limiting. Rather, any limitations to embodiments of the invention are presented in the following claims.

What is claimed is:

1. A method for fabricating semiconductor devices, comprising:
providing a bonded structure comprising a first substrate and a second substrate, a device structure between the first substrate and the second substrate, a release layer between the device structure and the first substrate, and a protective layer between the release layer and the first substrate, wherein the device structure includes a memory device formed on the second substrate; and
applying radiation to the release layer to detach the first substrate and protective layer from the release layer;
wherein the protective layer is transparent to the radiation.

2. The method of claim 1, wherein the protective layer includes silicon germanium, and the radiation includes infrared laser light with a wavelength of about 2 micrometers (μm) to about 10 μm.

3. The method of claim 1, wherein the step of providing a bonded structure comprises bonding the device structure to the second substrate through an oxide layer.

4. The method of claim 1, wherein after detaching the first substrate and protective layer from the release layer, the method further comprises:
polishing a surface of the protective layer through a chemical-mechanical polishing (CMP) process; and
epitaxially growing an additional layer from the polished surface.

5. The method of claim 4, wherein the release layer is a first release layer and the device structure is a first device structure, the method further comprising:
providing a second release layer on the additional layer; and
providing a second device structure on the second release layer.

6. The method of claim 1, further comprising:
removing the protective layer to expose a surface of the first substrate;
planarizing the surface of the first substrate through a gas cluster beam (GCB) process.

7. The method of claim 6,
wherein the release layer is a first release layer and the device structure is a first device structure, the method further comprising:
providing a second release layer on the first substrate; and
providing a second device structure on the second release layer.

8. The method of claim 1 wherein after detaching the first substrate and protective layer from the release layer, the method further comprises:
polishing a surface of the protective layer through a gas cluster beam (GCB) process to form a polished protective layer.

9. The method of claim 8, further comprising:
wherein the release layer is a first release layer and the device structure is a first device structure, the method further comprising:
providing a second release layer on the polished protective layer; and
providing a second device structure on the second release layer.

10. A method for fabricating semiconductor devices, comprising:
providing a bonded structure comprising a first substrate bonded to a second substrate, a device structure including a memory device provided between the first substrate and the second substrate, and a release layer between the device structure and the first substrate;
applying radiation to the release layer to detach the first substrate from the release layer;
planarizing first substrate; and
reusing the first substrate for a subsequent bonding process, wherein the subsequent bonding process includes bonding another device structure to the first substrate through another release layer.

11. The method of claim 10, wherein the first substrate comprises a base substrate and a protective layer between the base substrate and the release layer, the method further comprising planarizing at least a portion of the protective layer.

12. The method of claim 10, wherein the first substrate comprises a base substrate and a protective layer between the base substrate and the release layer, the method further comprising removing the protective layer and planarizing the base substrate.

13. The method of claim 11, wherein the protective layer includes silicon germanium, and the radiation includes infrared laser light with a wavelength of about 2 micrometers (μm) to about 10 μm.

14. The method of claim 13, further comprising:
polishing a surface of the protective layer through a chemical-mechanical polishing (CMP) process to form a polished protective layer; and
epitaxially growing an additional layer on the polished protective layer.

15. The method of claim 14, further comprising:
forming a transfer layer.

16. The method of claim 11, wherein the planarizing is performed using a gas cluster beam (GCB) process.

17. The method of claim 12, wherein the planarizing is performed using a gas cluster beam (GCB) process.

18. A method for fabricating semiconductor devices, comprising:
providing a substrate having structural damage caused by exposure to a radiation source in a first bonding process, the structural damage including an intermittent, semi-regular, or regular array of peaks;
planarizing the substrate by flattening or removing the peaks; and
providing and processing a series of layers on the substrate to form a device structure including a memory device.

19. The method of claim 18, wherein the substrate includes silicon or silicon germanium and utilizing the substrate comprises epitaxially growing an additional layer of silicon or silicon germanium over the substrate.

20. The method of claim 18, wherein the substrate includes a base substrate and a protective layer.

21. The method of claim 20, wherein the protective layer is removed and planarizing the substrate comprises planarizing the base substrate.

22. The method of claim 20, wherein planarizing the substrate comprises planarizing the base protective layer.

23. The method of claim 18, wherein the substrate is a first substrate, the method further comprising bonding the device structure to a second substrate.

24. The method of claim 23 further comprising directing radiation to the first substrate to cause the first substrate to detach from the device structure.
